(19) United States
(12) Patent Application Publication
(10) Pub. No.: US 2006/0012377 A1
(43) Pub. Date: Jan. 19, 2006

(54) Turbo engine

(76) Inventors: Thomas Bosselmann, Marloffstein (DE); Franz Eiermann, Rattelsdorf-Ebing (DE); Hans-Peter Heindel, Furth (DE); Wilfried Schnell, Fochheim (DE)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 10/533,014

(22) PCT Filed: Oct. 14, 2003
(86) PCT No.: PCT/DE03/03411

§ 371 Date: Apr. 28, 2005

(30) Foreign Application Priority Data
Nov. 6, 2002 (DE) 10251720.7

(51) Int. Cl. G01R 31/06

(52) U.S. Cl. 324/545

(57) ABSTRACT

The turbo engine comprises rotor blades made of an electrically conductive material with an electrically insulating surface, said rotor blades being rotatably mounted on a rotor shaft arranged in a housing. The electrically conductive material of the rotor blades is electrically connected to a reference potential. At least one measuring element is arranged in the area of the rotor blades, said measuring element being intended for measuring an electrical and/or magnetic field strength caused by charge distribution on the surface of the rotor blades.

### CROSS REFERENCE TO RELATED APPLICATION

This application is the US National Stage of International Application No. PCT/DE2003/003411, filed Oct. 14, 2003 and claims the benefit thereof. The International Application claims the benefits of German Patent application No. 10251720.7 DE filed Nov. 6, 2002, both of the applications are incorporated by reference herein in their entirety.

### FIELD OF THE INVENTION

The present invention relates to a turbo engine comprising rotor blades made of an electrically conducting material having an electrically insulating surface, said blades being arranged on a rotor shaft that is rotatably mounted in a housing. The invention also relates to a turbo engine comprising rotor blades arranged on a rotor shaft that is rotatably mounted in a housing, and comprising rotationally fixed guide blades made of an electrically conducting material having an electrically insulating surface.

### BACKGROUND OF THE INVENTION

Turbo engines having blade arrangements for interaction with a fluid flow flowing through the turbo engine are basically called compressors or turbines and the like. In order to increase the efficiency of such machines, ever greater physical demands are placed on the materials used in the turbo engine. In particular, in order to increase the efficiency of a gas turbine, the temperature of a gas flow flowing into the gas turbine is raised to more than 1200° C. So as to be able to withstand the high physical demands, in particular resulting from the temperature, the blades of the turbine are provided with a coating that withstands a particularly high stress. The thermal barrier coating, referred to below as TBC, of gas-turbine blades, is an example of such a coating, where such a coating is applied to that surface of a blade that is exposed to the gas flow.

This coating of the blade is subject to an aging that is dependent, among other factors, on the operating time and the other operating conditions of the blade. After reaching a defined operating time, the coating detaches from the blade, for example, which means that the blade is exposed without protection to the high stress presented by the gas flow. Immediate replacement of the blade is necessary in order to avoid this blade being destroyed and hence the turbine being damaged.

Thus in the prior art, operating times are specified for such blades, which once they have elapsed result in the turbine being dismantled and the blades being replaced or recoated even if the blades do not yet show any signs of damage. A disadvantage in this case is that, in order to avoid failures of blades and the turbine, the maintenance intervals are chosen to be so short or frequent as to make it highly improbable that a fault will occur between two maintenance intervals. It would therefore be desirable for such a turbo engine not to need to undergo maintenance until replacement or recoating of the blade is necessary, in particular in order to keep costs and downtimes low.

One option for ascertaining the damage to a coating of a blade before the blade itself is damaged is disclosed in U.S. Pat. No. 6,512,379. In the known device, gas flowing through the turbines exerts pressure on the turbine blades resulting in elastic deformations of the blade. In addition, friction between gas and blades is created by the flow around the blades. This results in radio frequency signals typically in the GHz range, generated by a pressure-induced piezoelectric effect, an expansion-induced electrostrictive effect or a friction-induced “tribo-charging” effect. The radio frequencies are detected by an RF antenna. Damage to the coating of a turbine blade results in a signal that differs with respect to the other blades. This indicates damage to the surface coating.

### SUMMARY OF THE INVENTION

The object of the present invention is to use a simple other option to ascertain the damage to a coating of a blade before the blade itself is damaged.

The solution proposed by the invention is that the electrically conducting material of the rotor blades is electrically connected to a reference potential, and the turbo engine comprises at least one measuring element, arranged in the region of the rotor blades, for measuring an electric and/or magnetic field strength set up by a charge distribution on the surface of the rotor blades.

Use is made of the effect that charges tend to “settle” on insulators, whereas they flow away on conducting materials. This is exactly the case for the TBC ceramic coating, on which charged particles from the ionized gas flow settle, while they flow away on uncoated metal. The quantity of charge on the coating is proportional to the TBC surface area, resulting in a measure of the integrity of the ceramic coating. If the rotor blades now rotate past a fixed antenna, it is possible to detect the charge differences, these being the differences from the region without blades (intermediate area) or between the individual blades, which provides information on defects in the TBC coating. A coaxial dipole antenna that projects into the gas flow can be used, for example, for the detection of the electric field generated by the charges (capacitive coupling), the frequency of said field (e.g. 4800 Hz) being obtained by multiplying rotational speed (e.g. 60 Hz) by number of blades (e.g. 80). The detection is therefore performed in the low frequency range. Information on the integrity of the blades can be obtained in the time domain from the amplitude height in the frame of e.g. 80 cycles (number of blades), or in the frequency domain from the appearance of harmonics of the rotational speed of e.g. 60 Hz. Under ideal conditions, in the time domain all amplitudes of the frame would be equal, or in the frequency domain it would not be possible to see any sub-harmonics below the 4800 Hz of the example.

By means of the invention it is possible for the first time to monitor the state of the blades, in particular continuously even during operation of the turbo engine, and to carry out a timely maintenance and/or overhaul of the turbine, in particular the blades, when a definable wear threshold is reached. As described above, the invention makes use of the effect that charges tend to collect on insulators, whereas on conducting materials they are conducted away by these materials. Charges occur in the flow of fluid materials either when the fluid itself is disassociated into relevant charge carriers, or when relevant charge carriers have been supplied to the fluid. The charge accumulated on an insulating layer may be proportional to its surface area, but is substantially dependent on the surface area. The charge carriers accumulated on the rotating rotor blades generate an electric field whose field strength can be detected by the measuring element. An indication of the field strength can thus be obtained by an analysis of the signals from the measuring element. An intact blade generates in the measuring element a corresponding characteristic amplitude of the measurement signal (e.g. electrical voltage). A worn coating on a rotor blade or a defective coating results in the charge being conducted away via the electrically conducting rotor blade to a reference potential that is electrically connected to the rotor blade. Such a blade can therefore generate a low-amplitude measurement signal in the measuring element. With rotation of the rotor shaft, all the blades of a blade wheel can be directed sequentially past the measuring element, so that it is possible to determine completely the state of the rotor blades of this rotor-blade wheel.

In a further embodiment it is proposed that the turbo engine comprises rotationally fixed guide blades made of an electrically conducting material having an electrically insulating surface, the electrically conducting material of the guide blades being electrically connected to a reference potential, and at least one measuring element being provided on the rotor shaft in the region of the guide blades, for measuring an electric and/or magnetic field strength set up by a charge distribution on the surface of the guide blades. Thus by exploiting the same effect, it is also possible to monitor an insulating surface provided on the guide blades. This further embodiment can also be combined with the aforementioned measures relating to ascertaining damage to the coated rotor blades.

It is also proposed that the measuring element is formed by a coaxial antenna. The coaxial antenna can advantageously have a very compact design and consequently be integrated easily in an existing structure. Furthermore, the coaxial antenna has favorable measuring properties whereby distortions or measurement errors can be kept low owing to the measurement principle used. Furthermore, using simple means, a coaxial antenna can be designed to withstand the high physical demands present at the intended measuring point. In principle, of course, other measuring elements can also be used, such as electrometers and the like. In addition, however, measuring elements can also be provided that generate a corresponding signal from the magnetic field generated by the movement of the charge. Thus the measuring element can also be designed as a measuring coil which can be used to detect changes in magnetic field, from which the state of the coating of the blades can be determined.

It is further proposed that the measuring element can be connected to a measuring unit. The measurement result supplied by the measuring element can advantageously be conditioned for further processing by means of the measuring unit.

Furthermore it is proposed that the measuring unit comprises a monitoring unit. The monitoring unit can be used, for example, to determine when a definable threshold value is reached, with maintenance of the turbo engine being planned when this threshold value is reached.

It is further proposed that the measuring unit has a communication link to a control center. This not only enables permanent transmission of a measurement result to the control center, for example in order to predict when maintenance is due or even to be able to initiate measures such as maintenance or activate spare units depending on the current state of wear, but also transmission of a threshold value being reached. The communication link can be implemented via radio, Internet or the like for example. The transmitted data can be saved in the control center for subsequent further processing.

In addition, it is proposed that the monitoring unit comprises a signaling and/or an alarm device. When a threshold value is reached, a warning can thus be issued to the operating staff so that appropriate measures can be taken in good time. A signaling device can be formed by a monitor, for example, on which the current measured values can be displayed. The values can also be displayed graphically on the monitor, however, and also compared with adjustable threshold values. When a threshold value is reached, an alarm device such as a warning lamp, flashing alarm lamp, a warning horn or the like can be actuated. A signal can also be sent to the control center however.

It is also proposed that the turbo engine can be shut down by means of the monitoring unit. This can advantageously result in the shutdown of the machine when defects on the blades are found, before the machine is damaged. Downtime, repair costs and repair time can be reduced.

In a further embodiment of the present invention, it is proposed that the turbo engine is a turbine, in particular a gas turbine. Particularly advantageously, it is possible to monitor continuously for damage to the coating of gas-turbine blades subject to particularly high stresses. This saves the need for specifying fixed maintenance intervals. Furthermore, the time at which maintenance is performed can be chosen according to need depending on the actual state of the blade. Downtimes and costs for premature maintenance can be reduced further. In addition, by saving and processing the measurement data appropriately, the quality of the blades used can advantageously be monitored. With a drop in quality, indicated by shorter maintenance intervals, suitable control of the blade machining process can be initiated.

The invention also proposes a method for determining damage to an electrically insulating surface of at least one rotor blade in a turbo engine, said blade being made of an electrically conducting material and arranged on a rotor shaft that is rotatably mounted in a housing, wherein an electric and/or magnetic field strength set up by a charge distribution on the surface of the rotor blades is measured by means of a measuring element, and a deviation from a definable threshold value is determined. Advantageously, it is possible to monitor the state of the surface of a blade and ascertain when a definable wear threshold is reached. A plurality of measuring elements can also be provided, however, whose measurement values are compared in parallel with correspondingly definable threshold values. Thus, for example, a redundancy in the measuring elements can be provided so that high reliability of the measurement can be achieved. This is particularly advantageous for large gas turbines used for supplying power, for which erroneous measurements would result in high costs. The state of a guide blade can also be determined, however, when a suitable measuring element is provided on the rotor shaft. The measurement method can be applied analogously.

The analogous method for determining damage to an electrically insulating surface of at least one guide blade in a turbo engine, said blade being made of an electrically conducting material and rotationally fixed in a housing, thus provides that an electric and/or magnetic field strength set up by a charge distribution on the surface of the at least one guide blade is measured by means of at least one measuring element arranged on the rotor shaft in the region of the guide blades, and a deviation from a definable threshold value is determined.

In addition, it is proposed that the deviation is transmitted to a control center. Advantageously a plurality of turbo engines can be monitored by one common control center so that the monitoring overhead can be reduced overall.

In order to be able advantageously to take an appropriate measure when the threshold value is exceeded, it is proposed that an alarm is output when the threshold value is exceeded. This can be performed by a control center, for example, although the measuring unit itself can also generate and output an alarm. The alarm can be output, for example on a suitable display unit that issues a visual or acoustic signal. The signal can also be issued by the control center, however, if the turbo engine is operated without technical staff in normal operation for example.

In addition, it is proposed that the turbo engine is shut down when the threshold value is exceeded. Thus a protective function can advantageously be achieved which can prevent a damaged surface leading to damage to the whole rotor blade. Even this measure can be performed by a control center for example. Suitable control devices which can be used to control the operation of the turbo engine can be provided on the turbo engine for this purpose.

In a further embodiment it is proposed that the measurement signal supplied by the measuring element is transformed, in particular by a Fourier transformation, by means of a measuring unit. The measurement signal supplied by the measuring element contains a frequency component generated by the movement of the discrete blades past the measuring element. Deviations from the normal value can be determined more clearly by the transformation of the measurement signal.

It is proposed that an FFT transformation unit is used for the purpose. The FFT transformation unit can be provided in the measuring unit, for example, or even in a remote control center. The measurement signal can be transformed continuously into a corresponding transformed signal by the FFT transformation unit. Continuous monitoring of the transformed signal can be achieved.

In order to determine the state of the blades, it is also proposed that the result of the transformation is displayed and signaled. Thus, for example, the result of the transformation can be communicated to a member of the operating staff in order to inform him of the state of the blades.

In order to generate a signal or to generate a criterion for the operation of the turbo engine, for example, it is proposed that the result of the transformation is compared with a definable threshold value. Particularly sensitive and accurate detection of the wear state of a blade can advantageously be achieved in this way. Even a slight reduction, which can be considered as a wear indicator, can be detected, so that appropriate measures can be taken in good time, such as replacing the blade or repairing the coating.

The threshold value can also be varied according to the blade or coating used, however, in order to be able to take into account different properties of the coating or a different load. Thus, for example, the threshold value for a blade at the fluid intake of the turbo engine can be set at a different level, for example, than for a blade at the fluid outlet of the turbo engine. In addition, the threshold value can also be defined as a function of other operating parameters of the turbo engine. Thus the threshold value can be set to a higher level when the turbo engine is operating under high load than when the turbo engine is under low load.

### BRIEF DESCRIPTION OF THE DRAWINGS

Further advantages and features are given in the following description of exemplary embodiments. Substantially identical components are labeled with the same reference numerals. In addition, where features and functions are identical, reference should be made to the description of the exemplary embodiment in FIG. 1.

FIG. 1 shows a perspective view of a gas turbine whose housing has been cut open along its length.

FIG. 2 shows a side view of a coated rotor blade of the gas turbine in FIG. 1,

FIG. 3 shows a side view of a coated guide blade of the gas turbine in FIG. 1,

FIG. 4 shows an enlarged view of the turbine and compressor region of the turbine in FIG. 1 having a measuring element according to the invention,

FIG. 5 shows a basic circuit diagram illustrating an operating procedure for the gas turbine shown in FIG. 1,

FIG. 6 shows a block diagram of a measuring device for measuring the measurement signal from the measuring element,

FIG. 7 shows a diagram displaying a Fourier transformation of the measurement signal measured using the measurement setup in FIG. 6 for the gas turbine running at 100% load.

FIG. 8 shows a diagram as in FIG. 7 with a transformed measurement signal for the turbine running at 30% of the rated load.

FIG. 9 shows a diagram as in FIG. 7 with a transformed measurement signal when the gas turbine is shut down when running at 100% load.

### DETAILED DESCRIPTION OF THE INVENTION

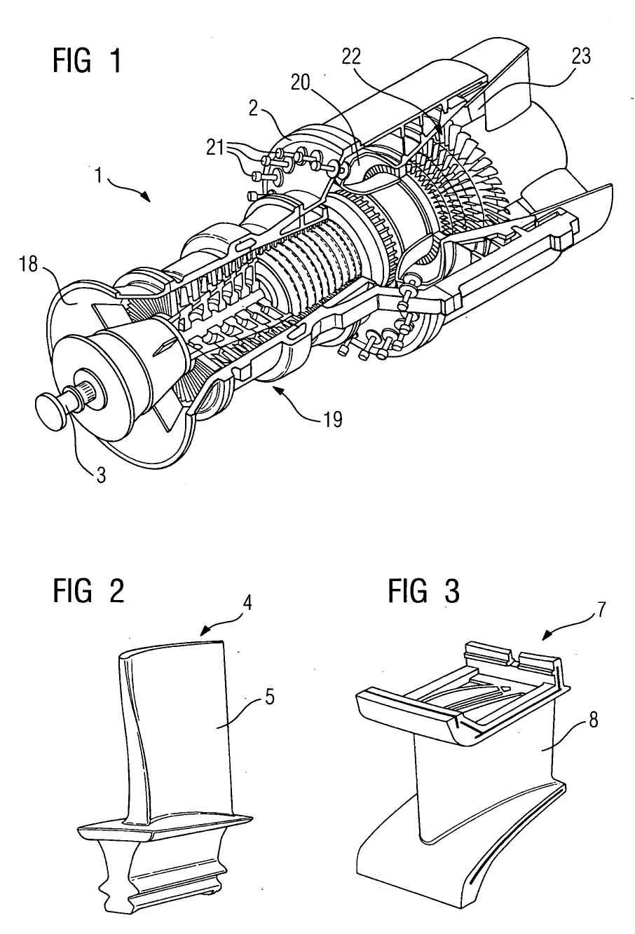

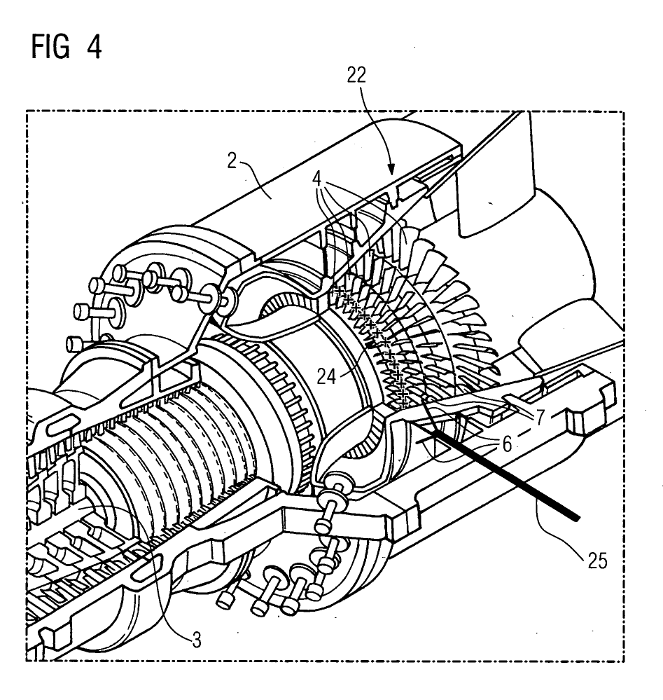

FIG. 1 shows a perspective view of a gas turbine 1 of the prior art comprising rotor blades 4 arranged on a rotor shaft 3 that is rotatably mounted in a housing 2 and comprising rotationally fixed guide blades 7. An air intake 18 is provided at one axial end, and a compressor 19 arranged axially after it. The compressor 19 is followed by a combustion chamber 20 having burners 21, the turbine area 22 with the gas outlet 23 being connected to this chamber. FIG. 4 shows an enlarged view of the turbine area 22. In FIG. 4, electric charges present on the surface of the rotor blades 4 are labeled with 24.

FIG. 2 shows an individual rotor blade 4 for arrangement on the rotor shaft 3, made of an electrically conducting material, preferably a metal such as steel or the like. The surface 5 of the rotor blade 4 is provided with an electrically insulating coating, here a ceramic coating.

FIG. 3 shows a corresponding guide blade 7, also made of an electrically conducting material, which also has a ceramic coating on its surface 8.

The rotor blades 4 are grounded via the rotor shaft 3 and a bearing (not shown in greater detail) of this rotor shaft 3. The guide blades 7 are likewise grounded via the housing 2 of the turbine 1.

During operation, hot process gas flows from the combustion chamber 20 through the turbine area 22 to the outlet 23. Owing to its high temperature of 1200° C., the gas flow contains ionized particles that tend to settle on the insulating surfaces. As a result, the surfaces 5, 8 of the blades 4, 7 become positively charged. As shown in FIG. 4, a coax antenna 6 is provided on the housing 2 opposite to the first row of rotor blades containing the blades 4. During rotation of the rotor shaft 3, this coax antenna detects the field changes of the electric field caused by the charge carriers located on the rotor blades 4. The coax antenna 6 generates, in time with the charges moving past, corresponding electric signals that are transmitted via a cable 25 to a measuring unit 10. The gas turbine 1 used in this example is designed for a speed of 3600 revolutions per minute, and has 80 rotor blades 4 arranged radially on the rotor-blade wheel located opposite to the coax antenna 6. Thus at the design speed, 4800 pulses per second are generated, corresponding to a frequency of 4800 Hz.

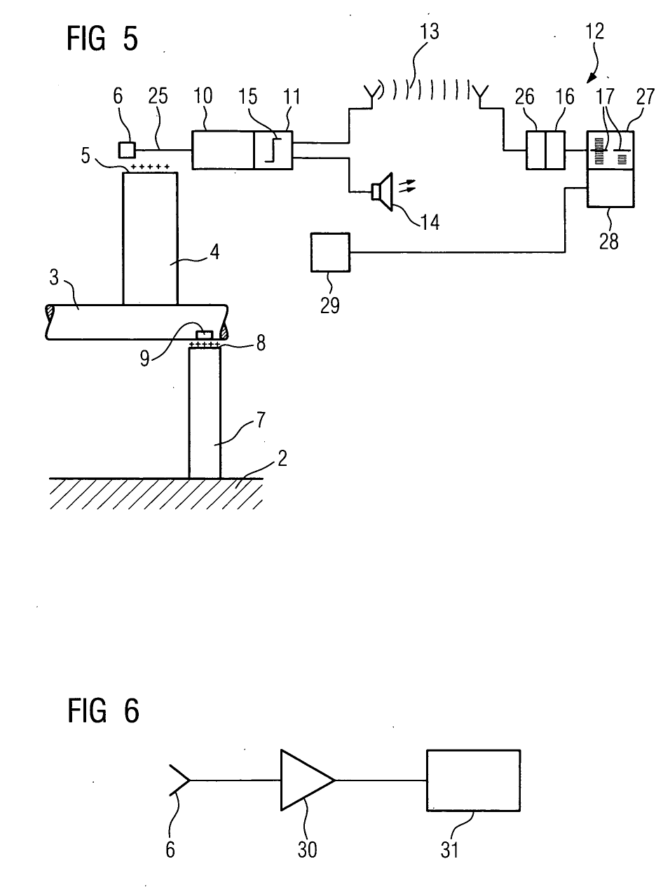

The measurement procedure is shown schematically in FIG. 5. FIG. 5 shows a section of the rotor shaft 3 of the turbine 1 comprising a rotor blade 4 arranged on it and a guide blade 7 fixed on the housing 2. The coax antenna 6 measures the local electric field and transmits a signal corresponding to the measurement value via the cable 25 to the measuring unit 10. The measuring unit 10 conditions the transmitted signals and sends them to a monitoring unit 11 contained in the measuring unit 10. The monitoring unit 11 compares the level of the conditioned signals with a definable threshold value 15, and when the signal level falls below this value transmits an appropriate alarm to a warning horn 14 and also sends a signal via a radio link 13 to a control center 12. The control center 12 comprises a receive unit 26, which receives and conditions the signals transmitted via the radio link 13. The received signals undergo a Fourier transformation in an FFT unit 16, e.g. Mathcad, and are displayed on a display 27. The display 27 can be formed by a monitor screen, for example, or even by rows of LEDs mounted in an enclosure. The display 27 also has adjustable threshold values 17 which can be used to indicate when the transformed signal level falls below threshold. A monitoring unit 28 continuously compares the transformed signal level with the threshold values, and when the signal level falls below a threshold value, transmits an appropriate signal to a control unit 29 of the turbine 1. The turbine 1 can be shut down via the control unit 29. Thus if wear is ascertained, the turbine 1 can be shut down and maintenance initiated.

A gas flow coaxial with rotor shaft 3 contains ions owing to its temperature of about 1200° C. The positive charge carriers of the gas flow deposit themselves on the insulating surfaces 5 of the blades 4. The charge carriers of the blades 4, which are carried past the coax antenna 6 by the rotation of the rotor shaft 3, create corresponding measurement signals that are processed according to the method. If damage to the insulating surface occurs on a blade 4, for example because of wear, the charge located on the surface 5 of the blade 4 decreases by being conducted away to ground at least partially via the metal body of the blade 4. The reduced amount of charge leads to a corresponding reduction in signal from the coax antenna 6, whereby the aforesaid measures are initiated automatically when the signal falls below a defined threshold value 15.

FIG. 5 also shows a corresponding monitoring for a guide blade 7, connected to the housing 2 of the turbine 1, said blade likewise having an insulating surface 8. The guide blades 7 are also correspondingly positively charged on their surface 8. A corresponding measuring element 9, designed as an induction sensor in this embodiment, is provided on the opposite shaft section of the rotor shaft 3. The induction sensor 9 rotates at the axial height of the guide-blade arrangement and measures in this way a magnetic field generated by the differential motion. The corresponding signal is transmitted via connections (not shown in greater detail) to a measuring unit designed for this purpose, which can have a communication link to the measuring unit 10 so as also to have an effect on the system of the gas turbine 1. In principle, however, a capacitive measuring element such as the coax antenna 6, for example, can also be provided at this point.

FIG. 6 shows a measurement setup for measuring the signals supplied by the coax antenna 6. The coax antenna 6 is connected to an amplifier 30 for this measurement, the output signal of which amplifier drives the input of a transient recorder 31, the time signal of which is transformed by an FFT in a PC.

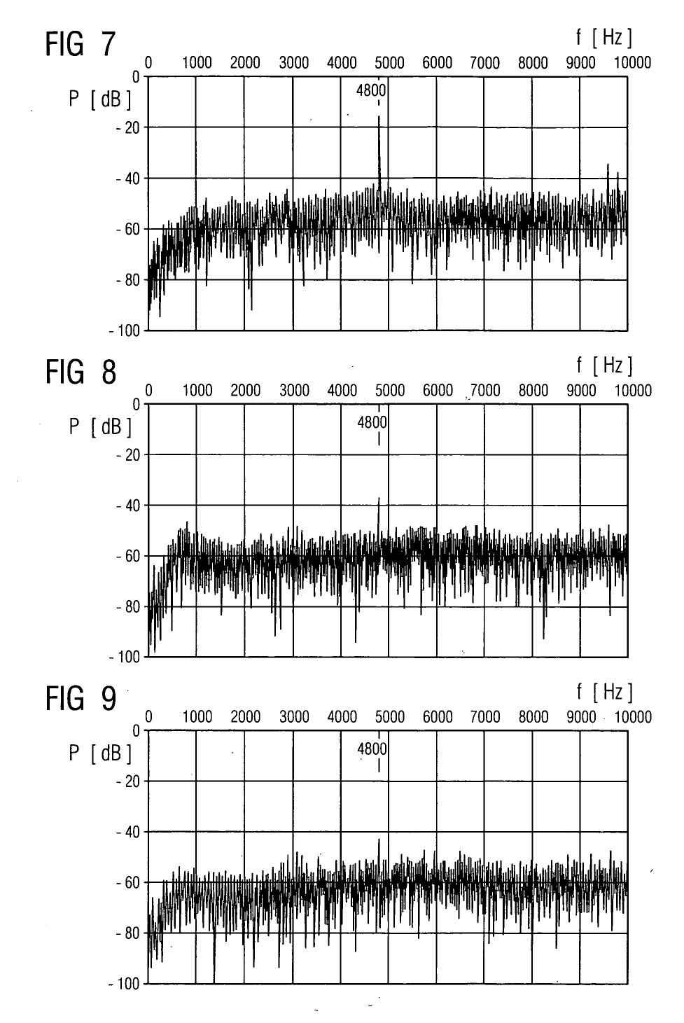

FIG. 7 shows a signal-level-frequency diagram of a data record, saved by the transient recorder and transformed in Mathcad, from the gas turbine 1 of FIG. 1 when operating under 100% load. The diagram has a Cartesian coordinate system whose ordinate gives the relative power level of the measured signal, while its abscissa is the frequency in Hertz. A single peak at the frequency of 4800 Hz, corresponding to the pulse sequence specified above, is clearly visible.

A diagram as in FIG. 7 is shown in FIG. 8, where the power equals just 30% of the rated power of the turbine 1. A peak at 4800 Hz is again quite clearly visible in this case.

FIG. 9 shows a diagram as in FIG. 7, but with the turbine 1 run down from 100% load to the idle state. Even in this case the peak at 4800 Hz is clearly visible. It can be seen here, however, that the ordinate value of the peak depends on the power of the turbine. Thus in order to achieve a practical monitoring of the coating, the threshold value 17 is corrected according to the current power state of the gas turbine 1. Thus the effectiveness of the coating on the surface 5, 8 of a blade 4, 7 can be found for every power state of the gas turbine 1 irrespective of the operating state of the gas turbine 1.

The exemplary embodiments shown in the figures serve merely to explain the invention and do not narrow its scope. Thus in particular the type of the measuring element or the further signal processing and the arrangement of the measuring element and also the number of the measuring elements used can vary without going outside the scope of protection of the invention. In particular, dual elements can obviously be used, for example a measuring element for a magnetic field instead of a measuring element for an electric field, because it involves the measurement of charges moved relative to the measuring element. In particular, the monitoring of the coating of a guide blade by means of a measuring element rotating with the rotor shaft is included. A plurality of measuring elements can advantageously be arranged in succession in the direction of the rotor axis. It is preferably possible for each measuring element to be assigned to a ring of turbine blades. It is thereby possible to determine on which ring precisely the damage to the surface coating has occurred. In addition it is possible using a synchronization pulse, for example correlated with the line frequency (e.g. 60 Hz), to determine on which blade precisely the damage to the surface coating has occurred.

1-20. (canceled)

21. A turbo engine, comprising:
a plurality of rotor blades made of an electrically conducting material having an electrically insulating surface and arranged on a rotor shaft that is rotatably mounted in a housing and electrically connected to a reference potential or a plurality of fixed guide vanes made of an electrically conducting material having an electrically insulating surface with the electrically conducting material of the guide vanes electrically connected to the reference potential; and
a measuring element for measuring an electric and/or magnetic field strength set up by a charge distribution on the surface of the rotor blades or guide vanes,
wherein the measuring element is arranged near the rotor blades and/or near the guide vanes.

22. The turbine engine as claimed in claim 21, wherein at least one measuring element is arranged on the rotor shaft in the region of the guide vanes.

23. The turbo engine as claimed in claim 22, wherein at least one measuring element is arranged in the region of the rotor blades and at least one measuring element is provided for measuring an electric and/or magnetic field strength set up by a charge distribution on the surface of the rotor blades.

24. The turbo engine as claimed in claim 23, wherein at least one measuring element is formed by a coaxial antenna.

25. The turbo engine as claimed in claim 23, wherein at least one measuring element is connected to a measuring unit.

26. The turbo engine as claimed in claim 25, wherein the measuring unit contains a monitoring unit.

27. The turbo engine as claimed in claim 25, wherein the measuring unit has a communication link to a control center.

28. The turbo engine as claimed in claim 26, wherein the monitoring unit comprises a signaling and/or an alarm device.

29. The turbo engine as claimed claim 26, wherein the turbo engine is shut down by the monitoring unit.

30. The turbo engine as claimed in claim 23, wherein the electrically insulating surface is formed by a coating.

31. The turbo engine as claimed in claim 23, wherein the turbo engine is a gas turbine.

32. A method for determining damage to an electrically insulating surface of a turbine component, comprising:
providing a plurality of turbine blades or vanes made of an electrically conducting material and arranged within a turbo engine;
creating an electric and/or magnetic field strength by a charge distribution on the surface of the turbine blade or vane;
measuring the electric and/or magnetic field strength by a measuring element; and
determining a deviation from a definable threshold value.

33. The method as claimed in claim 32, wherein the measuring element is arranged on a rotor shaft in the region of the vanes.

34. The method as claimed in claim 32, wherein the deviation is transmitted to a control center.

35. The method as claimed in claim 32, wherein an alarm is output when the definable threshold value is exceeded.

36. The method as claimed in claim 32, wherein the turbo engine is shut down when the definable threshold value is exceeded.

37. The method as claimed in claim 32, wherein a measurement signal supplied by the at least one measuring element is transformed by a Fourier transformation, by a measuring unit.

38. The method as claimed in claim 37, wherein a FFT transformation unit is used.

39. The method as claimed in claim 38, wherein a result of the transformation is displayed and/or signaled.

40. The method as claimed in claim 39, wherein the result of the transformation is compared with the definable threshold value.
